(19) United States
(12) Patent Application Publication
(10) Pub. No.: US 2014/0167759 A1
(43) Pub. Date: Jun. 19, 2014

(54) NMR BOREHOLE LOGGING DEVICE AND METHOD OF USE

(71) Applicants: Alexander Pines, Berkeley, CA (US); Vikram Bajaj, El Cerrito, CA (US); Scott J. Seltzer, Berkeley, CA (US)

(72) Inventors: Alexander Pines, Berkeley, CA (US); Vikram Bajaj, El Cerrito, CA (US); Scott J. Seltzer, Berkeley, CA (US)

(73) Assignee: The Regents of the University of California, Oakland, CA (US)

(21) Appl. No.: 14/033,037

(22) Filed: Sep. 20, 2013

Related U.S. Application Data
(60) Provisional application No. 61/738,921, filed on Dec. 18, 2012.
(60) Provisional application No. 61/738,930, filed on Dec. 18, 2012.

(51) Int. Cl. G01R 33/36

(52) U.S. Cl. CPC G01R 33/36
USPC 324/322

(57) ABSTRACT

This disclosure provides systems, methods, and apparatus related to depth well logging. In one aspect, an apparatus includes a radio frequency (RF) coil and a magnetic field sensing device. The apparatus is configured to be positioned in a first magnetic field. The first magnetic field polarizes nuclear spins of species in a detection region proximate the apparatus. The apparatus generates a second magnetic field for a time period with the RF coil to excite the nuclear spins of the species in the detection region. Then, the apparatus measures electromagnetic radiation, using the magnetic field sensing device, generated by the species as a result of the excitation of the nuclear spins.

### RELATED APPLICATIONS

This application claims priority to U.S. Provisional Patent Application No. 61/738,921, filed 18 Dec. 2012, and to U.S. Provisional Patent Application No. 61/738,930, filed 18 December 2012, both of which are herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to borehole logging and more particularly to NMR borehole logging apparatus and methods of use.

### BACKGROUND

Nuclear Magnetic Resonance (NMR) and Magnetic Resonance Imaging (MRI) can probe the morphology, chemistry, and chemical dynamics deep within opaque objects in their unaltered natural states; these unique capabilities account for their many applications to problems of chemical analysis and biological/medical analysis in laboratories and hospitals.

Conventionally, NMR experiments are performed on stationary samples in the strong magnetic field of a superconducting magnet. A sequence of radio frequency (RF) pulses, applied through an antenna that encloses the sample, perturbs the nuclear spin magnetization of species in the sample. The subsequent precession of the magnetization can be detected by the same antenna, yielding the chemically characteristic frequencies and line shapes of NMR spectra after inversion through Fourier transformation.

In the presence of a spatially varying magnetic field gradient, the same procedure yields an image of the spin density along the gradient axis. In this case, as well as in the case of conventional NMR techniques, the sensitivity of the experiment depends strongly on the fraction of the near field volume of the antenna that is filled by NMR-active nuclei.

Magnetic resonance is fundamentally limited by its insensitivity, however, due largely to the small equilibrium polarization of nuclear Zeeman spin states at ambient temperatures and ambient fields. As a result, a variety of technological and methodological developments, including strong superconducting magnets and methods for polarization transfer and hyperpolarization, have been developed to increase its sensitivity. This specialized and expensive infrastructure, however, renders MRI generally unsuitable for applications in which the samples are too small or too large, or for which portability and parallelism are desired.

### SUMMARY

Apparatus and methods disclosed herein may be operable to perform NMR measurements of a sample on portions of the sample that are significantly larger (e.g., about 10 times to 100 times, or more) than the size of a magnetic field sensing device. This technique generally uses a homogeneous background field so that the NMR resonance frequency is approximately uniform in the sample. The magnetic field sensing device may enable measurements at 2 kHz, in the magnetic field of the earth.

One innovative aspect of the subject matter described in this disclosure can be implemented in an apparatus including a radio frequency (RF) coil and a magnetic field sensing device. The apparatus is configured to be positioned in a first magnetic field, with the first magnetic field polarizing nuclear spins of species in a detection region proximate the apparatus. The apparatus generates a second magnetic field for a time period with the RF coil to excite the nuclear spins of the species in the detection region. The apparatus measures electromagnetic radiation, using the magnetic field sensing device, generated by the species as a result of the excitation of the nuclear spins.

In some embodiments, the magnetic field sensing device comprises a magnetometer. In some embodiments, the magnetometer comprises an alkali vapor cell magnetometer or a nitrogen-vacancy diamond-based magnetometer.

In some embodiments, the apparatus further includes an RF coil array including a plurality of RF coils, the RF coil being one of the plurality of RF coils. In some embodiments, the first magnetic field is substantially uniform. In some embodiments, the first magnetic field is a magnetic field of the Earth.

In some embodiments, the detection region extends about 1 meter to 5 meters from the apparatus. In some embodiments, the electromagnetic radiation is measured at an about 1 kHz to 3 kHz detection frequency. In some embodiments, the apparatus does not include a magnet to polarize the nuclear spins of the species in the detection region.

Another innovative aspect of the subject matter described in this disclosure can be implemented in a method including: (a) positioning an apparatus including a magnetic field sensing device and a radio frequency (RF) coil in a first magnetic field, the first magnetic field polarizing nuclear spins of species in a detection region proximate the apparatus; (b) generating a second magnetic field for a time period with the RF coil to excite the nuclear spins of the species in the detection region; and (c) measuring electromagnetic radiation, using the magnetic field sensing device, generated by the species as a result of the excitation of the nuclear spins.

In some embodiments, operations (b) and (c) are repeated, with results generated from operation (c) being averaged. In some embodiments, the first magnetic field is substantially uniform. In some embodiments, the first magnetic field is a magnetic field of the Earth.

In some embodiments, the apparatus does not include a magnet to polarize the nuclear spins of the species in the detection region. In some embodiments, the detection region extends about 1 meter to 5 meters from the apparatus. In some embodiments, operation (c) is performed at an about 1 kHz to 3 kHz detection frequency.

Another innovative aspect of the subject matter described in this disclosure can be implemented in an apparatus including a radio frequency (RF) coil, a magnetic field sensing device, and a magnet. The apparatus is configured to polarize nuclear spins of species in a detection region with a first magnetic field of the first magnet. After the first magnetic field of the magnet polarizes the nuclear spins of the species in the detection region, the apparatus is translated so that the magnetic field sensing device is proximate the detection region. The apparatus generates a second magnetic field for a time period with the RF coil to excite the nuclear spins of the species in the detection region. The apparatus then measures electromagnetic radiation, using the magnetic field sensing device, generated by the species as a result of the excitation of the nuclear spins.

In some embodiments, the magnet comprises a permanent magnet. In some embodiments, a strength of a magnetic field of the magnet is about 0.001 tesla to 0.01 tesla, and the magnetic field is substantially homogeneous within about 25 centimeters of the magnet. In some embodiments, the magnetic field sensing device and the magnet are positioned apart from one another in the apparatus.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a simulation of how the NMR signal increases as the measurement integrates out to further distances from a borehole logging device as described herein.

FIG. 2A shows an example of cross-sectional schematic diagram of a borehole logging device.

FIG. 2B shows an example of a top-down schematic diagram of a borehole logging device.

FIG. 3 shows an example of a flow diagram illustrating a method of borehole logging.

FIG. 4 shows an example of cross-sectional schematic diagram of a borehole logging device.

FIG. 5 shows an example of a flow diagram illustrating a method of borehole logging.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

### Introduction

A borehole may refer to any shaft bored in the ground, either vertically, horizontally, or at an arbitrary angle. A borehole may serve many different purposes, including the extraction of liquids (e.g., water, oil) or gasses (e.g., natural gas), as part of a geotechnical investigation, environmental site assessment, or mineral exploration. Borehole logging is the practice of measuring and assessing the geologic formations and the contents of the formations penetrated by a borehole; oil well logging is a specific type of borehole logging.

Magnetic resonance imaging (MRI), in its most familiar incarnation, uses large superconducting magnets to produce anatomically detailed and clinically relevant images of the soft tissues of the human body, which these magnets generally enclose. Increasingly, MRI is also used to analyze the nature of the rocks, sands, and fluids surrounding oil wells. These studies can involve measurements of porosity, transport, and fluid composition and are conducted using nuclear magnetic resonance (NMR) logging tools that incorporate permanent magnet assemblies that fit into the borehole. Data from such measurements are used in initial oil exploration, in oil extraction, and in secondary recovery from fields that are already producing or that might have produced in the past but have since become inactive, awaiting either new recovery techniques, or because their oil content is more difficult to extract, so awaiting commodity prices to rise enough that extraction is economically viable.

NMR oil-well logging differs from laboratory MRI principally because it uses an assembly of permanent magnets to project a magnetic field outward from the borehole. Such measurements in conventional NMR oil-well logging can generally probe only the first few inches of the oil-containing formation, and thus have limited statistical relevance, and are also complicated by the NMR response of the drilling fluid (fluid added to the borehole to lubricate the drill and resist the pressure of oil). These differences follow from the geometry of the setup (i.e., an ex-situ (inside-out) geometry versus an in-situ (enclosed) geometry) in borehole versus laboratory applications, and also from the use of inductive (flux) coils for NMR detection, whose sensitivity scales linearly with the detection frequency (and hence the magnetic field).

Disclosed herein are embodiments of NMR devices and methods with improved sensitivity and chemical specificity. In some embodiments, the methods may be used in petro-physical applications. In some embodiments, a sensitive optical detector of magnetic resonance (e.g., an optical magnetometer) that converts an insensitive NMR measurement into a sensitive optical polarization or fluorescence measurement, enhancing NMR sensitivity by at least about one or two orders of magnitude in low magnetic fields (e.g., less than about 0.25 tesla (T)), may be used.

### Device and Method of Use

Conventional NMR borehole logging tools can use arrangements of inductive detection coils, permanent magnet assemblies, and RF coils for spin excitation to detect NMR signals from concentric radial cylinders of material at increasing distances from a borehole wall. They require magnets not only to polarize the detected spins, but also because the sensitivity of inductive detection is sharply dependent on the NMR frequency. Since the permanent magnet assemblies necessarily produce strong magnetic field gradients, the dependence of NMR parameters on relevant petro-physical and petrochemical qualities need to be measured separately from their dependence on the locally varying magnetic field. Note that the use of permanent magnet assemblies that produce strong magnetic field gradients necessarily limits the depth from which signal can be detected. The field of the permanent magnet decreases sharply with distance, so that the detection coil may no longer have sufficient sensitivity to measure from regions where the NMR frequency is too low.

The high NMR frequencies (e.g., typically about 100 kHz to 3 MHz) involved in NMR detection with such tools also limit their application in encased wells, pipelines, and other situations where metal is between the NMR tool and the measured area. The metal screens the RF excitation signals from reaching the sample, and it also screens the NMR signal (i.e., oscillating radiation) from reaching the detector. This is often referred to as the skin effect. Metal also causes problems due to susceptibility artifacts at high frequency, but not at low frequency.

As an alternative, in some embodiments, atomic vapor cell and solid state (e.g., diamond) magnetometers may be used for borehole logging applications. At the frequencies employed in existing tools, the use of a magnetometer may improve measurement sensitivity by at least one order of magnitude. However, while still using strong permanent magnets for pre-polarization of spins, the sensitivity of magnetometer-based logging will not depend on the NMR frequency. As a result, the detection might be accomplished in far weaker and more homogeneous magnetic fields, ultimately including the magnetic field of the Earth. Such embodiments may log faster, with orders of magnitude greater sensitivity and chemical information, or with greater penetration into the formation. Further, in some embodiments, low-frequency magnetometry can be used to detect magnetic resonance images of samples enclosed in metal containers, or where the tool itself is what is enclosed in a metal container, as in the case of a metal-lined borehole. These embodiments may further be employed to perform the type of NMR measurements typical in borehole logging through or in the presence of metal, increasing the applicability of NMR logging in encased wells.

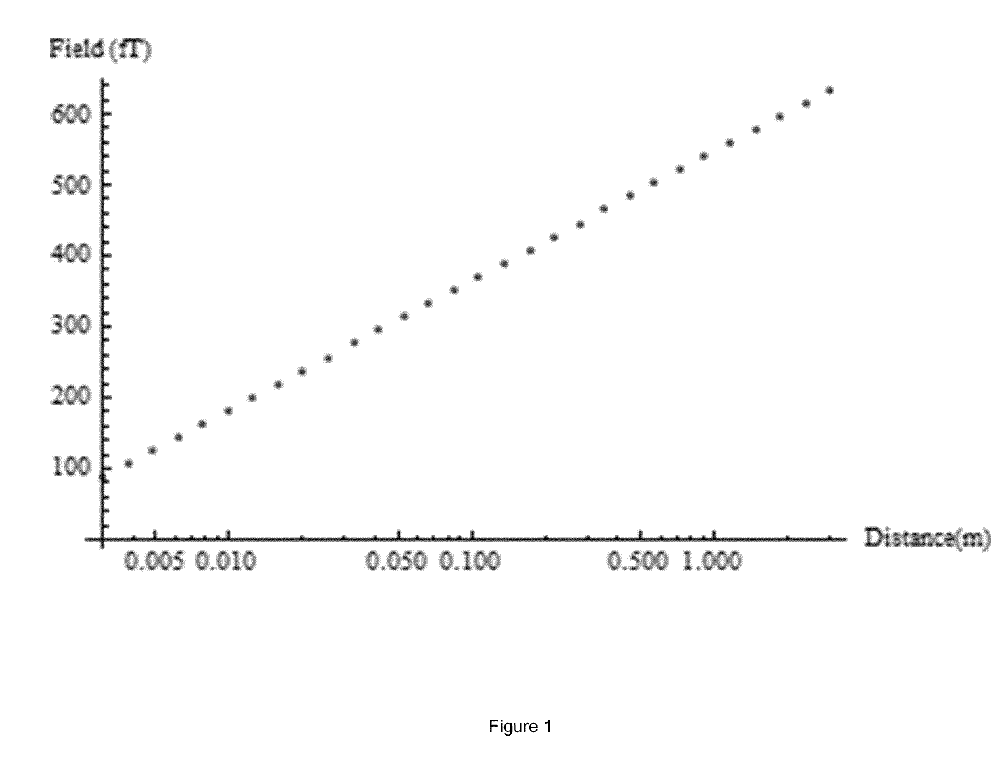

Further, a device that is able to detect signals from mixtures of water and oil magnetized in the magnetic field of the Earth using an optical atomic magnetometer may be able to resolve detectable signals from deep (e.g., meters to tens of meters) within the formation. FIG. 1 shows an example of a simulation of how the NMR signal increases as the measurement integrates out to further distances from a device as described herein. This is a substantial improvement over current capabilities.

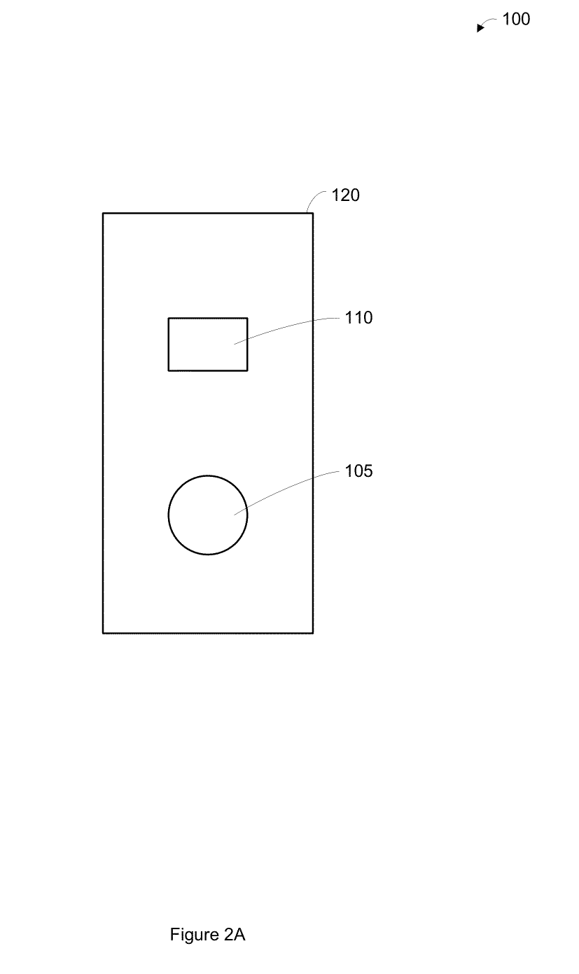

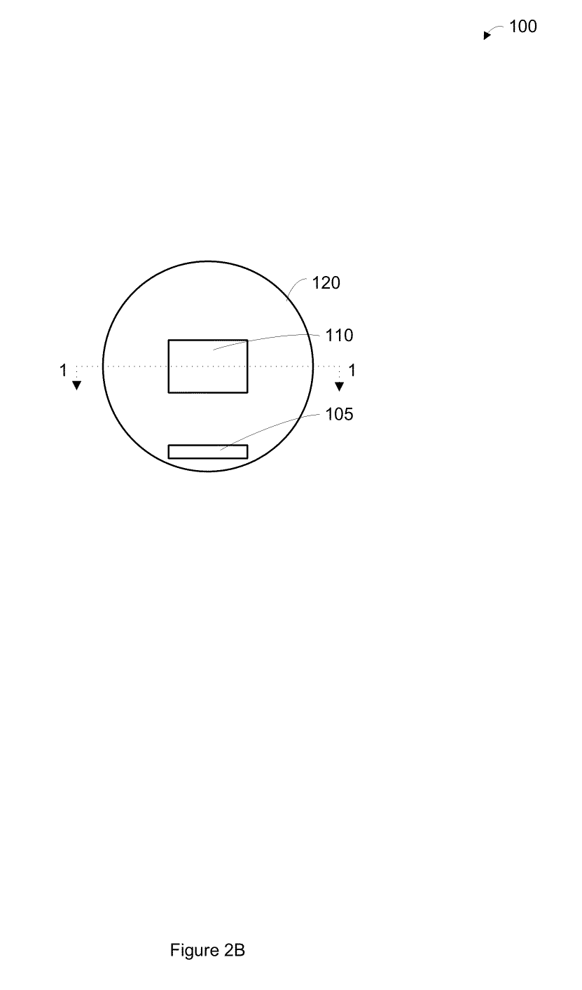

FIG. 2A shows an example of cross-sectional schematic diagram of a borehole logging device. FIG. 2B shows an example of a top-down schematic diagram of a borehole logging device. The schematic diagram shown in FIG. 2A is through line 1-1 of FIG. 2B.

As shown in FIGS. 1 and 2, a borehole logging device 100 includes a radio frequency (RF) coil 105 and a magnetic field sensing device 110. In some embodiments, the device 100 may include a housing 120 in which the RF coil 105 and the magnetic field sensing device 110 are positioned. In some embodiments, the borehole logging device 100 does not include a magnet (e.g., a permanent magnet).

In some embodiments, the housing 120 may be substantially in the shape of a cylinder. In some embodiments, the housing 120 may be sealed to the passage of fluids. In some embodiments, the RF coil 105 may be disposed on or about an inner surface of the housing 120.

In general, the size of the housing 120 depends on the size of the borehole into which the borehole logging device 100 is to be inserted. For example, the housing 120 may have a length of about a few inches to a few feet. The housing 120 may have a cross-sectional dimension (e.g., the view shown in FIG. 2B) of about a few inches. For example, if the housing 120 is cylindrically shaped, the length may be about a few inches to a few feet and the diameter may be about a few inches.

An RF coil generally consists of a conductor (e.g., a wire) wound into a coil-shape. An RF coil can be used to generate a dipole magnetic field or other magnetic field geometry by passing current though it. The RF coil 105 may include a metal trace, line, or wire arranged in coil-shape. The RF coil 105 may comprise any type of metal. In some embodiments, the RF coil 105 may be substantially circular. In some embodiments, the RF coil 105 may comprise a copper or aluminum trace, line, or wire arranged in a coil-shape. In some embodiments, the RF coil 105 may be operable to generate a dipole magnetic field in materials surrounding the borehole logging device 100.

In some embodiments, the RF coil 105 may be one RF coil of an RF coil array (not shown). An RF coil array incorporated with the borehole logging device 100 may include about 2 to 16 RF coils, for example. The RF coils of an RF coil array may be arranged to generate magnetic fields having specific characteristics (e.g., shape, strength, and the direction of the magnetic field vector), depending on the desired effect of the magnetic field in a material surrounding the borehole being measured.

In some embodiments, an RF coil array may include 3 sets of coils (i.e., one set of coils for each of the three spatial directions), with each set including 1 or 2 coils. In some embodiments, the 2 coils in a set of coils including 2 coils may be positioned as a Helmholtz pair; a Helmholtz pair includes two identical circular RF coils that are placed symmetrically one on each side of the experimental area along a common axis.

The magnetic field sensing device 110 may be almost any kind of magnetic field sensor. In some embodiments, the magnetic field sensing device 110 may comprise a magnetometer, a superconducting quantum interference device (SQUID), an inductive detector (e.g., such as a coil), a magnetoresistive sensor, a fluxgate, a Hall probe, or a cold atom sensor. A SQUID may have a sensitivity of about 0.1 femtotesla per root Hertz (fT/(Hz)^{1/2}) to 100 fT/(Hz)^{1/2}. An alkali vapor cell magnetometer, a nitrogen vacancy diamond magnetometer, and a SQUID are all capable of measuring signals at about 2 kHz (i.e., the proton resonance frequency in the magnetic field of the Earth of about 0.5 G) with high sensitivity. In embodiments in which the magnetic field sensing device 110 comprises a magnetometer, the magnetic field sensing device 110 may further include compensation coils (e.g., bias field coils, not shown) configured to generate a magnetic field to enable operation of the magnetometer.

In some embodiments, the magnetic field sensing device 110 may comprise an alkali vapor cell magnetometer. An alkali vapor cell magnetometer uses a spin polarized alkali atom gas as a medium in which changes in the properties of a polarized probe beam (e.g., direction or degree of polarization, or transmission of the beam through the medium) are detected in response to a magnetic field. While this variety of magnetometer has a large theoretical and demonstrated sensitivity, glass vapor cell engineering is complex, and cells may not be indefinitely miniaturized because of engineering challenges and because collisional wall relaxation processes at small cell dimensions begin to dominate the spin dynamics. Further, glass vapor cells may not have a bandwidth sufficient to record NMR spectra with chemical shift information. An alkali vapor cell magnetometer may have a sensitivity of about 0.001 fT/(Hz)^{1/2} to 100 fT/(Hz)^{1/2}. Further details regarding alkali vapor cell magnetometers can be found in U.S. Pat. No. 7,573,264, which is herein incorporated by reference.

In some embodiments, the magnetic field sensing device 110 may comprise a solid state magnetometer. Some advantages of solid-state magnetometers include size (i.e., solid-state magnetometers can be engineered to be significantly smaller than an alkali-vapor magnetometer) and superior robustness (i.e., it may be possible to better engineer the magnetometer for extreme conditions). Solid state magnetometers may be fabricated from engineered materials in which optical and magnetic (i.e., spin) degrees of freedom are coupled. In some embodiments, the solid state magnetometer may include the nitrogen-vacancy (NV) center defect in diamond (i.e., forming a nitrogen-vacancy diamond magnetometer). This defect is a spin-1 system that exhibits unusually long spin coherence times due to its weak coupling with the diamond lattice. It can be prepared in a spin polarized (i.e., pure) state simply by green light irradiation, and fluorescence emission depends strongly on the spin state. These properties make it a useful NMR detector. An ensemble of such defects in a diamond wafer may form the basis of a sensitive MRI sensor. A nitrogen vacancy diamond magnetometer may have a sensitivity of about 1 fT/(Hz)^{1/2} to 10⁵ fT/(Hz)^{1/2}. Further details regarding nitrogen vacancy diamond magnetometers can be found in Chang S. Shin, Claudia E. Avalos, Mark C. Butler, David R. Trease, Scott J. Seltzer, J. Peter Mustonen, Daniel J. Kennedy, Victor M. Acosta, Dmitry Budker, Alexander Pines, Vikram S. Bajaj, Room Temperature Operation of a Radiofrequency Diamond Magnetometer near the Shot Noise Limit, Journal of Applied Physics, 12, 124519 (2012), which is herein incorporated by reference.

While the sensitivity of an inductive flux detector depends on the frequency of the NMR signals, a magnetometer is sensitive even at low NMR frequencies. Both types of magnetometers described above may be at least one order of magnitude more sensitive at the ¹H NMR frequencies typical in NMR oil well logging applications, and at least about two to three orders of magnitude more sensitive in the magnetic field of the Earth, where the NMR frequencies are in the range of a few kHz. In some embodiments, this sensitivity can be exploited to increase the speed of the measurement or to increase its information content by encoding spectral or spatial information in the NMR signals.

In some embodiments, the borehole logging device 100 may further include a controller (not shown) having instructions for controlling components of the borehole logging device 100 and executing process operations in accordance with the disclosed embodiments. Alternatively, the borehole logging device 100 may include a control cable (not shown) able to transmit signals to and receive signals from components or a controller of the borehole logging device 100; e.g., a second controller for the borehole logging device 100 may be located apart from the device 100 itself. The controller may include one or more memory devices and one or more processors configured to execute the instructions so that the device will perform a method in accordance with the disclosed embodiments. Machine-readable media containing instructions for controlling process operations in accordance with the disclosed embodiments may be coupled to the system controller.

In some embodiments, the borehole logging device 100 may further include local data storage capabilities (not shown). This may allow the borehole logging device 100 to store measurements, and the measurements can be analyzed after the device has been removed from the borehole.

In some embodiments, the borehole logging device 100 may further include a low-bandwidth communication device (not shown) that enables communication with the surface when the borehole logging device 100 is in a borehole. For example, a limited amount of data may be transmitted to the surface which can be used to guide the drilling and logging process as it proceeds deeper into the ground.

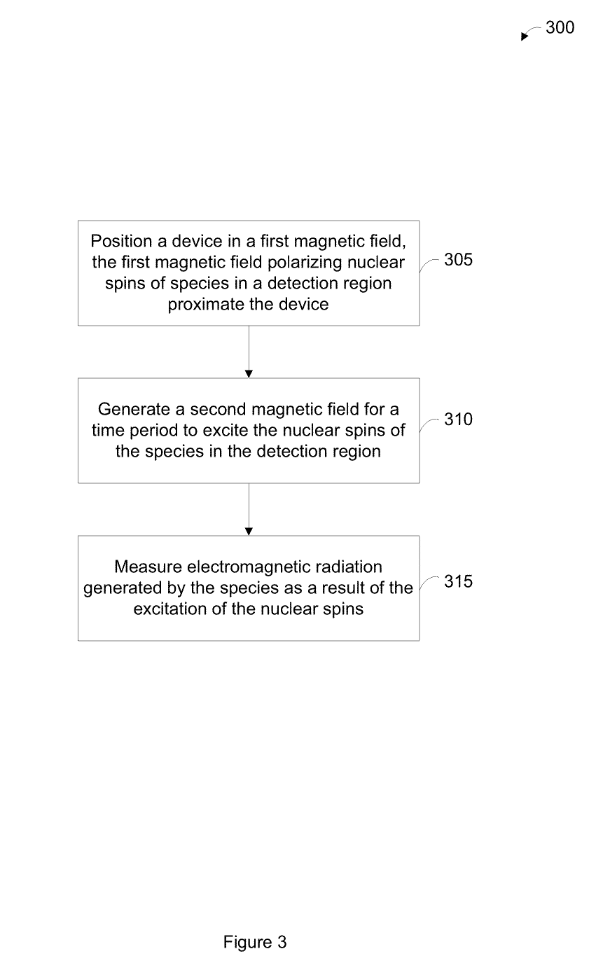

FIG. 3 shows an example of a flow diagram illustrating a method of borehole logging. The methods described below with respect to FIG. 3 may be implemented with embodiments of the borehole logging device 100 described with respect to FIGS. 1 and 2.

Starting at block 305 of the method 300 shown in FIG. 3, a borehole logging device including a magnetic field sensing device and a radio frequency (RF) coil is positioned in a first magnetic field. For example, the borehole logging device may be lowered into a borehole to a specific position. The first magnetic field polarizes nuclear spins of species in a detection region proximate the borehole logging device. In some embodiments, the detection region includes a volume of material surrounding the borehole logging device. In some embodiments, the detection region may extend about 1 meter to 5 meters or about 1 meter to 3 meters from the borehole logging device. In some embodiments, the detection region may extend about 0.1 meters to 0.5 meters from the borehole logging device.

In some embodiments, the first magnetic field may be substantially uniform. In some embodiments, substantially uniform may be taken to mean that there is no more than an about 10% to 20% variation in the magnetic field in the region of interest. In some embodiments, the first magnetic field is a magnetic field of the Earth (i.e., the ambient magnetic field at the location of the borehole) of about 0.05 mT. For example, in borehole logging applications, the borehole logging device may be lowered down a borehole and the first magnetic field may be the magnetic field of the Earth. In some embodiments, the borehole may comprise only the Earth; i.e., there may be no pipe or other structure in the borehole. In some embodiments, the borehole may include a metal tube or a metal pipe, with the borehole logging device being lowered down the metal tube or the metal pipe. In some embodiments, the electromagnetic radiation generated at block 315 may penetrate the metal tube or pipe (when the borehole includes a metal tube or a metal pipe) with acceptable attenuation due to the about 2 kHz proton resonance frequency in the magnetic field of the Earth.

In some embodiments, the first magnetic field may be an ambient magnetic field generated by a magnet or a coil external to the borehole logging device. For example, in borehole logging applications, the borehole logging device may be lowered down a first borehole. A magnet or a coil may be lowered down a second borehole, with the first borehole being proximate to the second borehole. The magnet or the coil may produce a magnetic field of a specific strength that polarizes nuclear spins of species in the detection region of the borehole logging device. The magnet or the coil could then be moved away from the detection region to allow for measurements by the borehole logging device.

At block 310, a second magnetic field is generated for a time period with the RF coil to excite the nuclear spins of the species in the detection region. In some embodiments, the second magnetic field is a radio frequency (RF) magnetic field. In some embodiments, the time period is about 1 millisecond to 5 seconds. For example, the time period over which the second magnetic field is generated may depend on a desired depth penetration of the magnetic field (e.g., the desired penetration depth of the second magnetic field into the species) or the size of the detection region, as well as size of the RF coil and the polarization lifetime of the spins in the species in the detection region. In some embodiments, a power of up to about 1 kilowatt (kW) may be applied to the RF coil to generate the second magnetic field. The strength of the second magnetic field depends in part on the power applied to the RF coil and the geometry or configuration of the RF coil.

In some embodiments, the second magnetic field may extend about 1 meter to 5 meters or about 1 meter to 3 meters from the borehole logging device. In some embodiments, the second magnetic field may extend about 1 meter to 5 meters or about 1 meter to 3 meters into a species proximate the borehole logging device and substantially perpendicular to a wall of a borehole in which the borehole logging device may be positioned. In some embodiments, the second magnetic field may extend about 0.1 meters to 0.5 meters from the borehole logging device. In some embodiments, the second magnetic field may extend about 0.1 meters to 0.5 meters into a species proximate the borehole logging device and substantially perpendicular to a wall of a borehole in which the borehole logging device may be positioned. In some embodiments, the second magnetic field may be substantially uniform. In some embodiments, substantially uniform may be taken to mean that there is no more than an about 10% to 20% variation in the magnetic field in the region of interest. In some embodiments, when the first magnetic field is the magnetic field of the Earth or another large, homogeneous, magnetic field, the second magnetic field may be seen as defining the size of the detection region.

In some embodiments, exciting the nuclear spins of the species in the detection region comprises tipping a component of the spins orthogonal to the first magnetic field. After tipping a component of a spin orthogonal to the first magnetic field, the spin will begin to precess and emit electromagnetic radiation at a frequency equal to the precession frequency.

In some embodiments, exciting the nuclear spins of the species in the detection region comprises flipping the spins; e.g., nuclear spins oriented in one direction are made to be oriented in an opposite direction. Repeatedly flipping the spins from one orientation to another causes a small change in the field level measured by the borehole logging device, and this field level flips back and forth (i.e., becomes slightly larger, then slightly smaller) at a rate equal to the spin flipping rate.

In some embodiments, a series of individual second magnetic fields may be generated to excite the nuclear spins of the species in the detection region. The series of second magnetic fields may generate a specific excitation profile (e.g., either spatial or temporal) of the nuclear spins of the species in the detection region.

At block 315, electromagnetic radiation generated by the species as a result of the excitation of the nuclear spins is measured using the magnetic field sensing device. In some embodiments, the electromagnetic radiation is measured at an about 1 kHz to 3 kHz detection frequency (i.e., a resonance frequency of the nuclear spins) or an about 2 kHz detection frequency when the spins are precessing in the ambient field of the Earth. In some embodiments, block 315 is performed for about 1 millisecond to 5 seconds. In some embodiments, the electromagnetic radiation may be generated by spin precession or by flipping the spin magnetization resulting from the second magnetic field generated at block 310.

For example, after block 310, the nuclear spins of the species in the detection region relax. Determining this relaxation time (e.g., by measuring the electromagnetic radiation) can be used to determine the materials (e.g., water versus oil, or different varieties of hydrocarbons) in the detection region. In some embodiments, the time period for performing block 315 depends on the relaxation time of the nuclear spins of the species in the detection region. The relaxation time can vary from milliseconds to seconds, depending on the species and the environment in which the species resides.

In some embodiments, the operations of blocks 310 and 315 may be repeated with the borehole logging device in the same position. The results of the measurements at block 315 may be averaged, which may improve the signal to noise ratio of the measurements. For example, after the nuclear spins of the species in the detection region relax and then repolarize (i.e., due to the first magnetic field), blocks 310 and 315 may be repeated. The repolarization time can vary from milliseconds to several seconds, depending on the material and its environment.

In some embodiments, the operations of blocks 310 and 315 may be repeated with the borehole logging device in the same position with the spatial excitation profile varying between at least some of the repetitions. This may enable imaging of the spins in the sample being measured by the borehole logging device.

In some embodiments, after operation 315, the borehole logging device may be translated to a new position. Blocks 305, 310, and 315 may then be repeated for a new or different detection region. For example, in a borehole logging application, the translation may be a vertical shift to look at a new region. In a borehole logging application, the borehole logging device may be translated thousands of meters to tens of thousands of meters in the borehole, with the borehole logging device recording data at specific intervals.

In some embodiments, translation of the borehole logging device may be used for imaging purposes. For example, as the device is translated, the nearby sample within the field of view of the device moves past the device quickly, while the portion of the sample at a deeper distance moves by the device more slowly. This is similar to the parallax effect. This could be taken into account to extrapolate which parts of the signal come from nearby spins (e.g., which could change very quickly), and which parts of the signal come from far-away spins (e.g., which could change much more slowly).

In some embodiments, non-uniformities in the second magnetic field (e.g., magnetic field gradients) generated using the RF coil, which may in turn produce a distribution of excitations of the nuclear spins, may be used to generate an image of the species in the detection region. By repeating the measurement some number of times, with different distributions of the non-uniformities of the second field, more robust methods for imaging may be implemented.

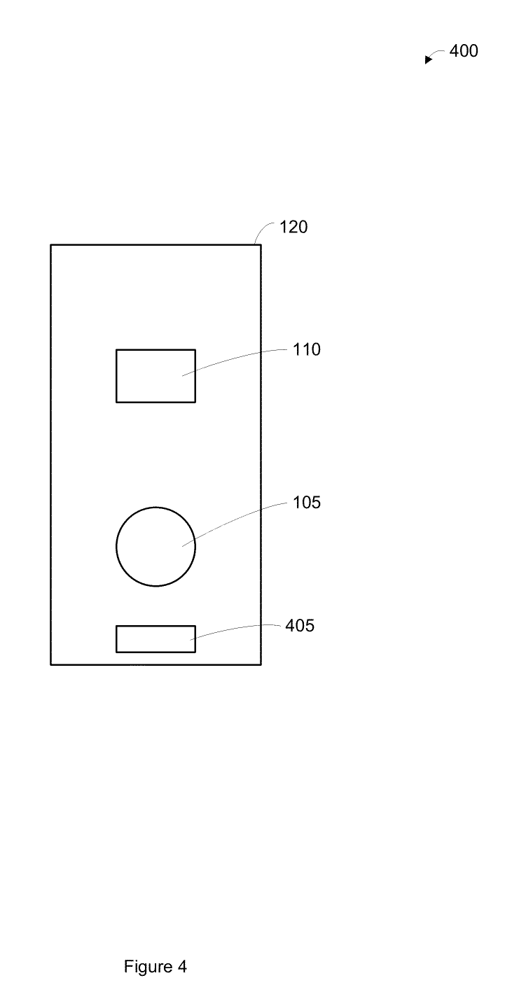

FIG. 4 shows an example of cross-sectional schematic diagram of a borehole logging device. A borehole logging device 400 may be similar to the borehole logging device 100 described with respect to FIGS. 1 and 2, with the addition of a magnet.

As shown in FIG. 4, the borehole logging device 400 includes a radio frequency (RF) coil 105, a magnetic field sensing device 110, and a magnet 405. In some embodiments, the device 100 may include a housing 120 in which the RF coil 105, the magnetic field sensing device 110, and the magnet 405 are positioned.

Similar to the borehole logging device 100, in some embodiments, the RF coil 105 of the borehole logging device 400 may comprise a metal (e.g., copper or aluminum) trace, line, or wire arranged in a coil-shape. In some embodiments, the RF coil 105 may be one RF coil of an RF coil array (not shown). In some embodiments, the magnetic field sensing device 110 may comprise a magnetometer, a superconducting quantum interference device (SQUID), an inductive detector (e.g., such as a coil), a magnetoresistive sensor, a fluxgate, a Hall probe, or a cold atom sensor.

In some embodiments, the magnet 405 comprises a permanent magnet. In some embodiments, the magnet 405 includes an array or an arrangement of magnets. In some embodiments, a strength of a magnetic field of the magnet 405 is about 0.001 tesla (T) to 0.01 T. In some embodiments, the strength of the magnetic field of the magnet 405 may be lower than the strength of a magnet included in a current NMR borehole logging device, which may include a magnet having a magnetic field of about 0.05 T to 0.2 T, for example.

In some embodiments, a magnetic field of the magnet 405 may be substantially homogeneous within about 25 centimeters (e.g., along a radius of the apparatus 400) of the magnet 405. In some embodiments, substantially homogenous may be taken to mean that there is no more than an about 10% to 20% variation in the magnetic field in the region of interest. It is generally not possible to generate such a homogeneous magnetic field with the stronger magnets (e.g., a magnet having a magnetic field of about 0.05 T to 0.2 T) used in current NMR borehole logging devices.

In some embodiments, the magnetic field of the magnet 405 may not be substantially homogeneous. The variations in the spin polarizations generated with the magnet 405 that does not have a substantially homogeneous magnetic field may be used to enable spatial imaging of the sample.

In some embodiments, the magnetic field sensing device 110 and the magnet 405 are positioned apart from one another in the borehole logging device 400. The magnetic field sensing device 110 and the magnet 405 may be positioned apart from one another in the borehole logging device 400 so that the field of the magnet 405 does not interfere with the operation of the magnetic field sensing device 110. The distance between the magnetic field sensing device 110 and the magnet 405 is determined in part by the size of the magnet 405 and the profile of the magnetic field of the magnet 405. For example, in some embodiments, the magnetic field sensing device 110 and the magnet 405 may be separated by about 3 inches to 3 feet or about 3 feet to 10 feet along an axis of the borehole logging device 400. In some embodiments, the field of the magnet 405 at the position of the magnetic field sensing device 110 may be compensated for.

With the magnet 405, the borehole logging device 400 may be able to measure a stronger signal compared to the borehole logging device 100 described above. The stronger signal may be generated due to the greater spin polarization that the magnet 400 may generate compared to the spin polarization generated by the magnetic field of the Earth or an ambient magnetic field; spin polarization generally scales linearly with magnetic field strength, and NMR signal scales linearly with spin polarization.

The detection region of the borehole logging device 400, however, may be a smaller volume than the borehole logging device 100 due to the magnetic field of the magnet 405 not extending as far from the device 400 as the first magnetic field used in the operation of the borehole logging device 100.

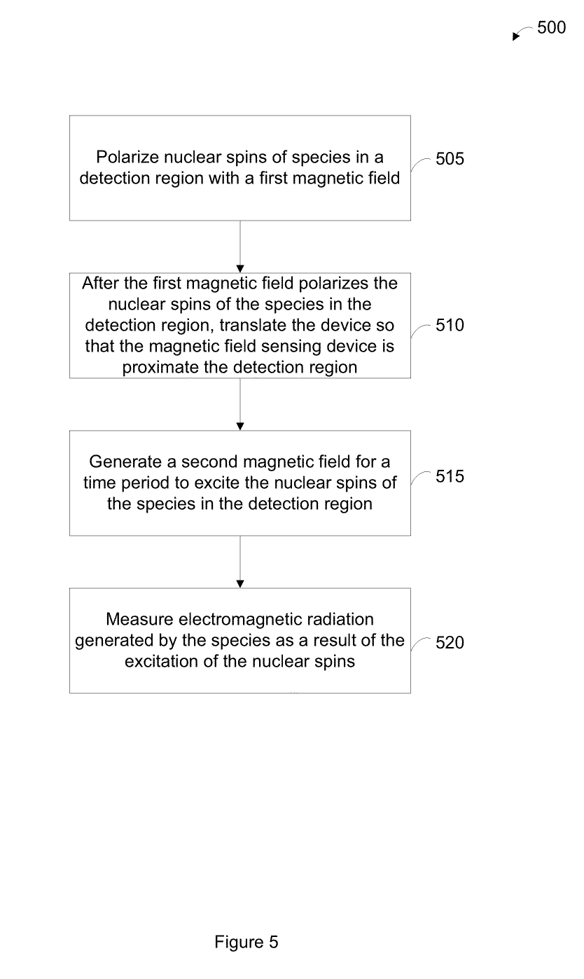

FIG. 5 shows an example of a flow diagram illustrating a method of borehole logging. The methods described below with respect to FIG. 5 may be implemented with embodiments of the borehole logging device 400 described with respect to FIG. 4.

Beginning at block 505 of the method 500, a borehole logging device including a radio frequency (RF) coil, a magnetic field sensing device, and a magnet is positioned so that a first magnetic field of the magnet polarizes nuclear spins of species in a detection region.

At block 510, after the first magnetic field of the magnet polarizes the nuclear spins of the species in the detection region, the borehole logging device is translated so that the magnetic field sensing device is proximate the detection region. For example, when the borehole logging device is positioned in a borehole, the device may be translated vertically (i.e., up or down) in the borehole. The nuclear spins that were polarized at block 505 may remain polarized for milliseconds to seconds.

At block 515, a second magnetic field is generated for a time period with the RF coil to excite the nuclear spins of the species in the detection region. In some embodiments, block 515 may be similar to block 310 of the method 300 described with respect to FIG. 3.

At block 520 electromagnetic radiation generated by the species as a result of the excitation of the nuclear spins is measured using the magnetic field sensing device. In some embodiments, block 520 may be similar to block 315 of the method 300 described with respect to FIG. 3.

In some embodiments, when the first magnetic field is substantially homogeneous, the borehole logging device may not be translated at block 510. For example, if magnetic field compensation can be engineered to be sufficient, the magnet and magnetic field sensing device may be positioned close to one another, and detection can occur in the field of the magnet.

One feature of the borehole logging devices and methods described herein is that they employ a magnetic field (e.g., either generated by the device or an ambient magnetic field) that is larger than the device itself. In some embodiments, this may allow for the measurement of species positioned many length scales from the device.

The devices and methods described herein may be used for borehole logging, and more specifically for oil well logging. Many other applications are possible. The concepts disclosed herein can be applied to instances in which the detection region is substantially larger than the magnetic field sensing device itself (e.g., up to about 10 to 100 times larger, if not more), and a homogeneous magnetic field is present or can be introduced.

For example, the possibility of carbon sequestration in features such as oil wells and penetrating geological formations depends on a precise understanding of operative hydrological transport mechanisms, porosity, and structure of the rock, and the dynamics of multiphasic flow within it. The techniques disclosed herein developed to solve the reciprocal problem—that of producing fossil fuels from oil wells—is equally applicable in this case. MRI detected optically with an alkali vapor magnetometer or ensemble nitrogen-vacancy (NV) magnetometer does not depend on high signal frequency for high sensitivity and may deliver two orders of magnitude better sensitivity in this application. However, their sensitivity to the NMR signal still depends on the sample polarization, which in turn scales linearly with field. In some embodiments, a magnet can be used to increase polarization, as described above. The improvement from not requiring high detection frequency (i.e., one dependence on field strength, rather than two different dependences as with inductive detectors) may be enough so that these sorts of measurements may take a reasonable, albeit potentially long, amount of time, making them feasible. This may open up the possibility of recording images of geological features in Earth's magnetic field. Further, such sensors may eventually be affordable enough that they can be left in place for long-term monitoring of sequestration projects.

As another example, the devices and methods described herein may be used to monitor the flow and chemical composition of liquids flowing in pipelines, where the pipeline flows coaxially with the axis of the device, or the device, smaller than the pipeline, is inserted from an orthogonal port. An example of this use is the metering of oil/water fraction in petrochemical pipelines.

As yet another example, the devices and methods described herein may be used to monitor a region in the human body or other animal. For example, a millimeter or micrometer sized device (e.g., using a diamond magnetometer) could be incorporated with a catheter which is then placed in an artery or vein, and the region surrounding the artery or vein could be characterized. The first magnetic field could be generated by placing the body of the person or animal in a MRI scanner which can generate a very homogeneous field over the length scales of interest in this case. The second magnetic field (e.g., the magnetic field generated by the RF coil) may extend up to about 1 mm (millimeter) to 5 centimeters (cm) or about 1 cm to 10 cm from the device. For example, a millimeter-sized catheter may be used to measure features that are much larger (e.g., about 1 cm to 10 cm) away from it.

### Conclusion

The following publications describe concepts related to the embodiments disclosed herein, and are all herein incorporated by reference:

T. Theis, P. Ganssle, G. Kervern, S. Knappe, J. Kitching, M. P. Ledbetter, D. Budker, A. Pines, Parahydrogen-enhanced zero-field nuclear magnetic resonance, Nature Physics 7, 571-575 (2011); and

Micah Ledbetter, Igor M. Savukov, Dmitry Budker, Vishal Shah, Svenja Knappe, John Kitching, David J. Michalak, Shoujun Xu, and Alexander Pines, Zero-field remote detection of NMR with a microfabricated atomic magnetometer, Proc. of the Nat. Acad. Sci. 105 (7), 2286-2290 (2008).

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. An apparatus comprising:
a radio frequency (RF) coil; and
a magnetic field sensing device, the apparatus being configured to:
be positioned in a first magnetic field, the first magnetic field polarizing nuclear spins of species in a detection region proximate the apparatus,
generate a second magnetic field for a time period with the RF coil to excite the nuclear spins of the species in the detection region, and
measure electromagnetic radiation, using the magnetic field sensing device, generated by the species as a result of the excitation of the nuclear spins.

2. The apparatus of claim 1, wherein the magnetic field sensing device comprises a magnetometer.

3. The apparatus of claim 2, wherein the magnetometer comprises an alkali vapor cell magnetometer or a nitrogen vacancy diamond-based magnetometer.

4. The apparatus of claim 1, further comprising:
an RF coil array including a plurality of RF coils, the RF coil being one of the plurality of RF coils.

5. The apparatus of claim 1, wherein the first magnetic field is substantially uniform.

6. The apparatus of claim 1, wherein the first magnetic field is a magnetic field of the Earth.

7. The apparatus of claim 1, wherein the detection region extends about 1 meter to 5 meters from the apparatus.

8. The apparatus of claim 1, wherein the electromagnetic radiation is measured at an about 1 kHz to 3 kHz detection frequency.

9. The apparatus of claim 1, wherein the apparatus does not include a magnet to polarize the nuclear spins of the species in the detection region.

10. A method comprising:
(a) positioning an apparatus including a magnetic field sensing device and a radio frequency (RF) coil in a first magnetic field, the first magnetic field polarizing nuclear spins of species in a detection region proximate the apparatus;
(b) generating a second magnetic field for a time period with the RF coil to excite the nuclear spins of the species in the detection region; and
(c) measuring electromagnetic radiation, using the magnetic field sensing device, generated by the species as a result of the excitation of the nuclear spins.

11. The method of claim 10, wherein operations (b) and (c) are repeated, and wherein results generated from operation (c) are averaged.

12. The method of claim 10, wherein the first magnetic field is substantially uniform.

13. The method of claim 10, wherein the first magnetic field is a magnetic field of the Earth.

14. The method of claim 10, wherein the apparatus does not include a magnet to polarize the nuclear spins of the species in the detection region.

15. The method of claim 10, wherein the detection region extends about 1 meter to 5 meters from the apparatus.

16. The method of claim 10, wherein operation (c) is performed at an about 1 kHz to 3 kHz detection frequency.

17. An apparatus comprising:
a radio frequency (RF) coil;
a magnetic field sensing device; and
a magnet, the apparatus being configured to:
polarize nuclear spins of species in a detection region with a first magnetic field of the first magnet,
after the first magnetic field of the magnet polarizes the nuclear spins of the species in the detection region, be translated so that the magnetic field sensing device is proximate the detection region,
generate a second magnetic field for a time period with the RF coil to excite the nuclear spins of the species in the detection region, and
measure electromagnetic radiation, using the magnetic field sensing device, generated by the species as a result of the excitation of the nuclear spins.

18. The apparatus of claim 17, wherein the magnet comprises a permanent magnet.

19. The apparatus of claim 17, wherein a strength of a magnetic field of the magnet is about 0.001 tesla to 0.01 tesla, and wherein the magnetic field is substantially homogeneous within about 25 centimeters of the magnet.

20. The apparatus of claim 17, wherein the magnetic field sensing device and the magnet are positioned apart from one another in the apparatus.
